(19) United States
(12) Patent Application Publication
(10) Pub. No.: US 2010/0326487 A1
(43) Pub. Date: Dec. 30, 2010

(54) THERMOELECTRIC ELEMENT AND THERMOELECTRIC DEVICE

(75) Inventors: Tomoyuki Komori, Osaka (JP); Tsutomu Kanno, Kyoto (JP); Hideaki Adachi, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Kadoma-shi, Osaka (JP)

(21) Appl. No.: 12/865,073

(22) PCT Filed: Nov. 17, 2009
(86) PCT No.: PCT/JP2009/006153

§ 371 Date: Jul. 28, 2010

(30) Foreign Application Priority Data
Nov. 21, 2008 (JP) 2008-297548
Nov. 21, 2008 (JP) 2008-297549
Nov. 21, 2008 (JP) 2008-297550

(51) Int. Cl. H01L 35/32

(52) U.S. Cl. 136/226

(57) ABSTRACT

The present invention provides thermoelectric elements, each of which can transfer heat efficiently to a heat source with a curved surface, such as a columnar heat source. A thermoelectric element of the present invention includes a laminate with two different types of thermoelectric conversion materials that are layered alternately from one end to the other end as well as a first electrode and a second electrode that are disposed at both ends of the laminate, respectively, wherein the laminate has a shape surrounding a straight line axis from the one end to the other end, when viewed from the direction along the axis, the laminate has an inner circumference with a circular or arc shape and each boundary between respective layers formed of the two different types of thermoelectric conversion materials is disposed in such a manner as to separate from a straight line as the boundary approaches an outer circumference from the inner circumference of the laminate, where the straight line passes an inner circumference-side edge point of the boundary, with the axis being a starting point thereof.

### TECHNICAL FIELD

The present invention relates to thermoelectric elements and thermoelectric devices that convert thermal energy into electrical energy.

### BACKGROUND ART

Thermoelectric generation technology is a technology for directly converting thermal energy into electrical energy using the Seebeck effect, in which an electromotive force is generated in proportion to a temperature difference created between both ends of a substance. This technology has been used practically, for example, for a remote area power supply, an outer space power supply, and a military power supply.

The performance of a thermoelectric conversion material used for a thermoelectric device often is evaluated by a figure of merit Z, or a figure of merit ZT that is obtained by multiplying a figure of merit Z by absolute temperature to be non-dimensionalized. The figure of merit ZT can be expressed as ZT=S²T/ρκ, where S is a Seebeck coefficient, ρ is electrical resistivity, and κ is thermal conductivity, of a substance. The FIG. S²/ρ, which is expressed by the Seebeck coefficient S and electrical resistivity ρ, is a value referred to as a power factor. The power factor is used as a measure for determining the quality of the power generation performance of, for example, the thermoelectric conversion material and the thermoelectric device under a constant temperature difference.

A Bi-based material that currently is used practically as a thermoelectric conversion material has relatively high properties with a ZT of approximately 1 and a power factor of 40 to 50 μW/cmK² under the present conditions. However, an ordinary π-type thermoelectric device containing the Bi-based material used therein cannot be said to have a sufficiently high power generation performance for being used in a wider range of applications. The π-type thermoelectric device is a device with a configuration in which a thermoelectric conversion material composed of a p-type semiconductor and a thermoelectric conversion material composed of n-type semiconductor, having carriers of opposite signs, are connected to each other so as to be thermally in parallel and electrically in series. Furthermore, an example of the thermoelectric device other than that of the π type is a thermoelectric device that takes advantage of the anisotropy of thermoelectric properties of natural or artificially-produced layered structures, which has long been proposed (see, for example, Non-Patent Literature 1). However, even this thermoelectric device cannot be said to have a sufficiently high power generation performance. Moreover, Patent Literature 1 describes a thermoelectric device that has two electrodes and a laminate that is interposed between the two electrodes and is composed of Bi₂Te₃ layers and metal layers that are layered alternately, with a layer surface of the laminate being inclined with respect to the direction in which the two electrodes are opposed to each other. This thermoelectric device has a high power generation performance.

### [Prior Art Literature]

### [Patent Literature]

### [Patent Literature 1] JP 4124807 B

### [Non-Patent Literature]

### [Non-Patent Literature 1] A. A. Snarskii, P. Bulat, “THERMOELECTRICS HANDBOOK”, Chapter 45, CRC Press (2006)

### DISCLOSURE OF INVENTION

However, since the conventional thermoelectric device has a flat plate shape, there has been a problem that it cannot transfer heat efficiently with respect to a heat source with a curved surface, such as a columnar heat source.

The present invention was made with the above situation in mind and is intended to provide thermoelectric elements and thermoelectric devices that can transfer heat efficiently with respect to, for example, heat sources with a curved surface, such as columnar heat sources.

The present inventors made various studies and found that the above-mentioned object was achieved by the following present invention. That is, a thermoelectric element of the present invention includes a laminate with two different types of thermoelectric conversion materials that are layered alternately from one end to the other end, and a first electrode and a second electrode that are disposed at both ends of the laminate, respectively, wherein the laminate has a shape surrounding a straight line axis from the one end to the other end, when viewed from the direction along the axis, the laminate has an inner circumference with a circular or arc shape and each boundary between respective layers formed of the two different types of thermoelectric conversion materials is disposed in such a manner as to separate from a straight line as the boundary approaches an outer circumference from the inner circumference of the laminate, where the straight line passes an inner circumference-side edge point of the boundary, with the axis being a starting point thereof.

Furthermore, a thermoelectric device of the present invention includes a plurality of thermoelectric elements, wherein the plurality of thermoelectric elements each include a laminate with two different types of thermoelectric conversion materials that are layered alternately from one end to the other end, the laminate has a shape surrounding a straight line axis from the one end to the other end, when viewed from the direction along the axis, the laminate has an inner circumference with a circular or arc shape and each boundary between respective layers formed of the two different types of thermoelectric conversion materials is disposed in such a manner as to separate from a straight line as the boundary approaches an outer circumference from the inner circumference of the laminate, where the straight line passes an inner circumference-side edge point of the boundary, with the axis being a starting point thereof., and the plurality of thermoelectric elements are connected to each other electrically in series.

Moreover, a thermoelectric device of the present invention includes a plurality of thermoelectric elements, wherein the plurality of thermoelectric elements each include a laminate with two different types of thermoelectric conversion materials that are layered alternately from one end to the other end, the laminate has a shape surrounding a straight line axis from the one end to the other end, when viewed from the direction along the axis, the laminate has an inner circumference with a circular or arc shape and each boundary between respective layers formed of the two different types of thermoelectric conversion materials is disposed in such a manner as to separate from a straight line as the boundary approaches an outer circumference from the inner circumference of the laminate, where the straight line passes an inner circumference-side edge point of the boundary, with the axis being a starting point thereof, and the plurality of thermoelectric elements are connected to each other electrically in parallel.

From another aspect, the present invention also provides a thermoelectric element including a laminate formed of a material that contains two different types of thermoelectric conversion materials layered alternately from one end to the other end and that is disposed so as to incline towards an outer circumference from an inner circumference of the material with respect to a straight line extending between a center point surrounded by the material and a point on a boundary between the two different types of thermoelectric conversion materials on the inner circumference of the material, a first electrode disposed at the one end, and a second electrode disposed at the other end. In this case, the laminate has a shape surrounding a straight line axis while extending from one end to the other end. The center point is the axis when the laminate is viewed from the direction along the axis. Furthermore, when the laminate is viewed from the direction along the axis, the respective thermoelectric conversion materials are disposed in such a manner as to separate towards the outer circumference from the inner circumference of the laminate with respect to a straight line extending between the center point and a point on a boundary between the two different types of thermoelectric conversion materials on the inner circumference of the laminate.

The thermoelectric elements and thermoelectric devices of the present invention are practical because they can transfer heat efficiently with respect to heat sources with a curved surface, such as columnar heat sources, and also have high power generation properties. The present invention promotes application of energy conversion between heat and electricity and therefore has a high industrial value.

The present invention can provide thermoelectric elements and thermoelectric devices that can transfer heat efficiently with respect to, for example, heat sources with a curved surface, such as columnar heat sources.

### BRIEF DESCRIPTION OF THE DRAWINGS

FIG. 1 is a diagram showing an example of a thermoelectric element according to the present invention.

FIG. 2 is a diagram showing an example of a laminate of the thermoelectric element according to the present invention, which is viewed from the direction along the axis.

FIG. 3A is a diagram showing a structure retainer used for producing a thermoelectric element according to the present invention.

FIG. 3B is a perspective view of a piece of a thermoelectric conversion material layer used for producing a thermoelectric element according to the present invention.

FIG. 3C is a side view of the piece of a thermoelectric conversion material layer used for producing a thermoelectric element according to the present invention.

FIG. 3D is a diagram showing a first step, which illustrates an example of the method of producing a thermoelectric element according to the present invention.

FIG. 3E is a diagram showing a second step, which illustrates an example of the method of producing a thermoelectric element according to the present invention.

FIG. 3F is a diagram showing a third step, which illustrates an example of the method of producing a thermoelectric element according to the present invention.

FIG. 4 is a diagram showing an operational state of a thermoelectric element of the present invention.

FIG. 5A is a diagram showing another example of the laminate of a thermoelectric element according to the present invention, which is viewed from the direction along the axis.

FIG. 5B is a diagram showing another example of the laminate of a thermoelectric element according to the present invention, which is viewed from the direction along the axis.

FIG. 5C is a diagram showing another example of the laminate of a thermoelectric element according to the present invention, which is viewed from the direction along the axis.

FIG. 6A is a diagram showing another example of a thermoelectric element according to the present invention.

FIG. 6B is a diagram showing another example of a thermoelectric element according to the present invention, which is viewed from the direction along the axis.

FIG. 7 is a diagram showing an example of a thermoelectric device according to the present invention.

FIG. 8 is a diagram showing another example of a thermoelectric device according to the present invention.

### DESCRIPTION OF THE PREFERRED EMBODIMENTS

Hereinafter, embodiments of the present invention are described with reference to the drawings.

### Embodiment 1

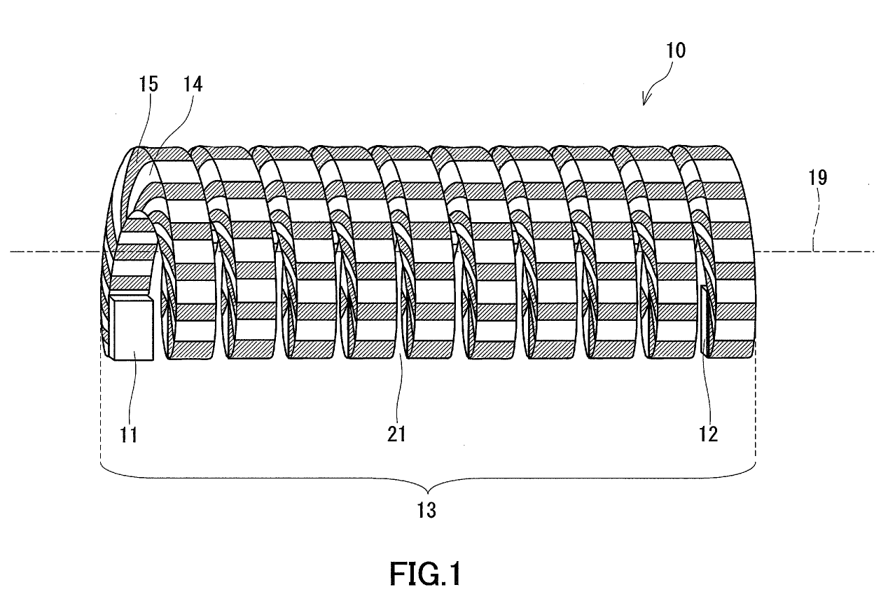

FIG. 1 is a diagram showing an example of a thermoelectric element according to the present invention. As shown in FIG. 1, the thermoelectric element 10 according to the present invention includes a laminate 13 as well as a first electrode 11 and a second electrode 12 that are disposed at both ends of the laminate 13, respectively. The laminate 13 has a shape surrounding a straight line axis 19 from one end to the other end and has a shape spirally extending around the axis 19. The laminate 13 is wound at sufficient intervals in the direction along the axis 19, with a space 21 being formed, so that the wound portions are not in contact with each other. The laminate 13 has a structure including first thermoelectric conversion material layers 14 and second thermoelectric conversion material layers 15 that are layered alternately from one end to the other end.

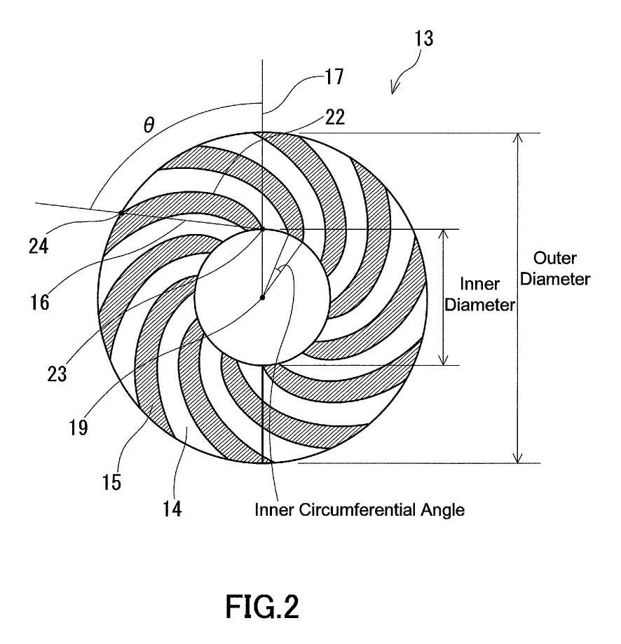

FIG. 2 is a diagram showing an example of a laminate of the thermoelectric element according to the present invention, which is viewed from the direction along the axis. As shown in FIG. 2, the first and second thermoelectric conversion material layers 14 and 15 each extend between the inner circumference and the outer circumference of the laminate 13 and are curved. Boundaries 22 between the respective first and second thermoelectric conversion material layers 14 and 15 each are disposed so as to be a curved line that separates from the straight line 17 as each boundary 22 approaches the outer circumference from the inner circumference of the laminate 13, where the straight line 17 passes the inner circumference-side edge point 23 of each boundary 22, with the axis 19 being the starting point thereof. The straight line 17 is a normal line of the inner circumference of the laminate 13 at the inner circumference-side edge point 23. Furthermore, the line segment 16 extending between the inner circumference-side edge point 23 and the outer circumference-side edge point 24 of each boundary 22 and the straight line 17 form preferably an angle θ of 15° to 210°. In this case, the first and second thermoelectric conversion material layers 14 and 15 are not necessarily curved, but when they are curved, the thermoelectric element 10 can obtain a higher power factor. Moreover, all the angles θ of the respective first and second thermoelectric conversion material layers 14 and 15 may not be necessarily the same value. That is, the respective first and second thermoelectric conversion material layers 14 and 15 may include layers with different angles θ.

Preferably, a thermoelectric conversion material composing the first thermoelectric conversion material layers 14 and a thermoelectric conversion material composing the second thermoelectric conversion material layers 15 are different from each other and have large differences in thermal conductivity K and Seebeck coefficient S from each other. This allows the thermoelectric element 10 to generate a large amount of electricity. Furthermore, it is preferable that the thermoelectric conversion materials each have a low electrical resistivity. For example, the thermoelectric conversion materials each are preferably metal and specifically may be a material containing Bi, a material containing Bi and Te, a material containing Pb and Te, or Cu, Ag, Au, or Al. Preferably, one of the thermoelectric conversion materials is a material containing Bi, a material containing Bi and Te, or a material containing Pb and Te. In that case, the other is preferably Cu, Ag, or Au and particularly preferably Cu or Ag. Furthermore, the material containing Bi and Te is preferably Bi₂Te₃, and the material containing Pb and Te is preferably PbTe. These materials may deviate in composition according to the production condition, but it is acceptable as long as the followings hold: Bi₂Teₓ. (2<x<4) and PbTe_{y} (0<y<2).

The materials used for the first electrode 11 and the second electrode 12 are not particularly limited as long as they have high electrical conductivity. Specifically, the first electrode 11 and the second electrode 12 can be formed using metal such as Cu, Ag, Mo, W, Al, Ti, Cr, Au, Pt, or In, nitride such as TiN, or oxide such as indium tin oxide (ITO) or SnO₂. Furthermore, the first electrode 11 and the second electrode 12 may be formed using, for example, a solder, a silver brazing, or a conductive paste.

Since air is present in the space 21 to provide electrical insulation, the laminate 13 does not short-circuit. Furthermore, air is preferable because it has high thermal insulation properties and therefore can reduce heat loss from the space 21. Moreover, the space 21 may be filled with an electrical insulator. This increases the strength of the thermoelectric element 10. The insulator can be, for example, an epoxy resin, paraffin, rubber polyvinyl chloride, alumina, or glass but an epoxy resin is preferable because it has high thermal insulation properties.

The present inventors studied various conditions with respect to the thermoelectric element 10, examined the relationship with the thermoelectric performance in detail, and thereby tried to optimize the thermoelectric element 10. As a result, they found that when the angle θ, the ratio of the inner circumferential angles of the first thermoelectric conversion material layers 14 and the second thermoelectric conversion material layers 15, and the ratio of the inner and outer diameters of the laminate 13 were set suitably according to the material composing the second thermoelectric conversion material layers 15, the thermoelectric element 10 obtained a high power generation performance. In this case, the inner circumferential angles are values that indicate the thicknesses of the first thermoelectric conversion material layers 14 and the second thermoelectric conversion material layers 15 in the circumferential direction in the inner circumference of the laminate 13 when the laminate 13 is viewed from the direction along the axis 19, in terms of the angles formed with the axis 19 being the vertex (see FIG. 2).

Preferably, the material composing the second thermoelectric conversion material layers 15 contains Bi. In this case, it is particularly preferable that the angle θ be 30° to 120°. Furthermore, the ratio of the inner circumferential angles of the first thermoelectric conversion material layer 14 and the second thermoelectric conversion material layer 15 is preferably in the range of 0.2:1 to 250:1 and particularly preferably in the range of 5:1 to 20:1. Moreover, the ratio of the inner and outer diameters of the laminate 13 is preferably in the range of 1:1.1 to 1:100 and particularly preferably in the range of 1:1.5 to 1:2.

Preferably, the material composing the second thermoelectric conversion material layers 15 contains Bi and Te. In this case, it is particularly preferable that the angle θ be 60° to 90°. Furthermore, the ratio of the inner circumferential angles of the first thermoelectric conversion material layer 14 and the second thermoelectric conversion material layer 15 is preferably in the range of 0.05:1 to 250:1 and particularly preferably in the range of 5:1 to 40:1. Moreover, the ratio of the inner and outer diameters of the laminate 13 is preferably in the range of 1:1.1 to 1:10 and particularly preferably 1:1.5.

Preferably, the material composing the second thermoelectric conversion material layers 15 contains Pb and Te. In this case, it is particularly preferable that the angle θ be 60° to 90°. Furthermore, the ratio of the inner circumferential angles of the first thermoelectric conversion material layer 14 and the second thermoelectric conversion material layer 15 is preferably in the range of 0.2:1 to 100:1 and particularly preferably in the range of 5:1 to 40:1. Moreover, the ratio of the inner and outer diameters of the laminate 13 is preferably in the range of 1:1.05 to 1:10 and particularly preferably in the range of 1:1.2 to 1:1.5.

With respect to each material composing the second thermoelectric conversion material layers 15, when the respective conditions are in the above-mentioned ranges, the thermoelectric element 10 has very practical values of power factor.

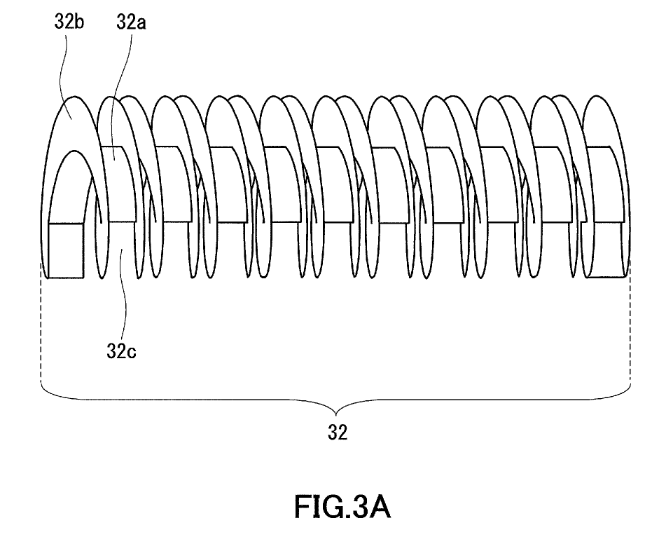

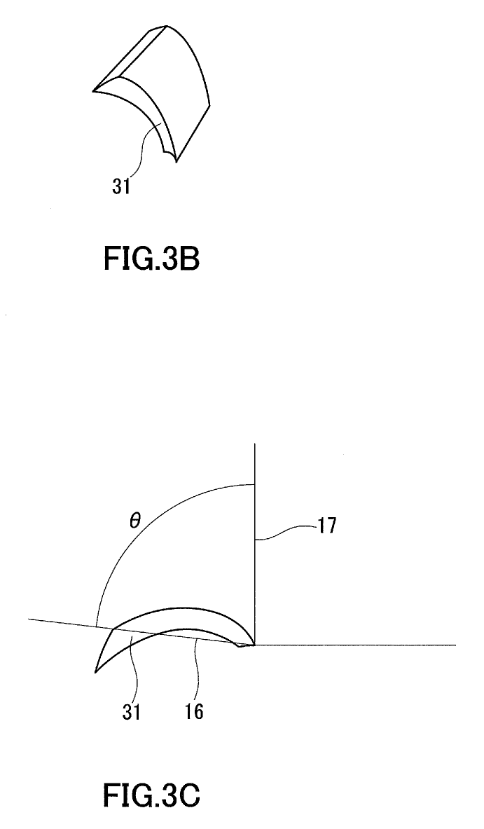

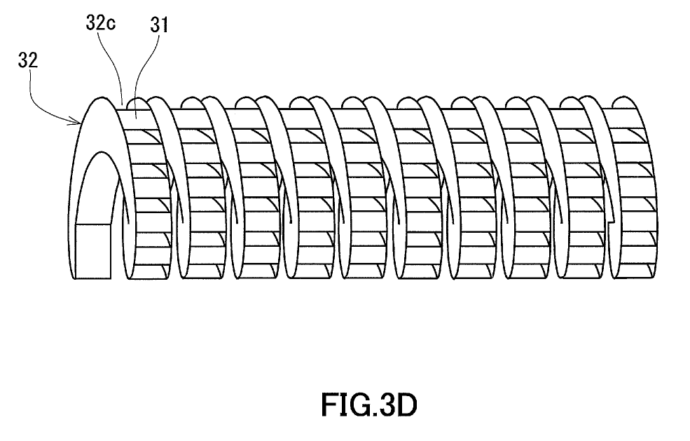

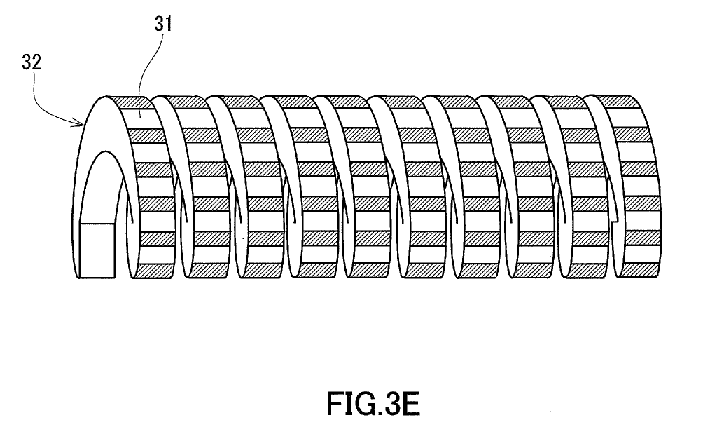

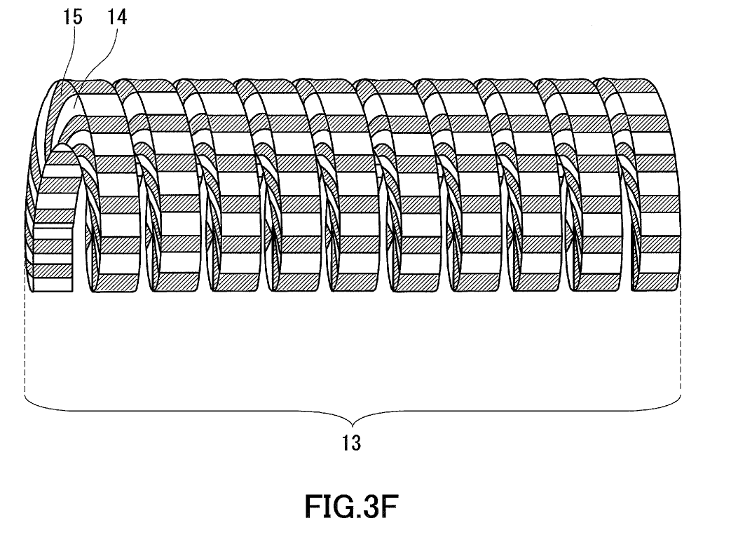

FIG. 3A is a diagram showing a structure retainer used for producing a thermoelectric element according to the present invention. FIG. 3B is a perspective view of a piece of a thermoelectric conversion material layer used for producing a thermoelectric element according to the present invention. FIG. 3C is a side view of the piece of a thermoelectric conversion material layer used for producing a thermoelectric element according to the present invention. FIGS. 3D to 3F are diagrams showing first to third steps, which illustrate an example of the method of producing a thermoelectric element according to the present invention.

In order to produce the thermoelectric element 10, first, the structure retainer 32 shown in FIG. 3A is prepared. The structure retainer 32 includes a band portion 32a with a spiral shape and guide portions 32b disposed along the sides of the band portion 32a that are opposed to each other and thereby a spiral-shaped groove 32c is formed. The thermoelectric conversion material layer piece 31 shown in FIGS. 3B and 3C is a member corresponding to the first or second thermoelectric conversion material layer 14 or 15 shown in FIG. 1. When the later steps are taken into consideration, it is preferable that the thermoelectric conversion material layer piece 31 correspond to one of the first and second thermoelectric conversion material layers 14 and 15, which is composed of a material with a higher melting point. When the material composing the first thermoelectric conversion material layers 14 has a higher melting point than that of the material composing the second thermoelectric conversion material layers 15, it is preferable that the thermoelectric conversion material layer piece 31 correspond to the first thermoelectric conversion material layer 14. The thermoelectric conversion material layer piece 31 is obtained by cutting the material composing the first thermoelectric conversion material layers 14 into the same shape as that of the first thermoelectric conversion material layers 14. Moreover, polishing processing may be carried out after cutting, if necessary.

As shown in FIG. 3D, thermoelectric conversion material layer pieces 31 are placed in the groove 32c of the structure retainer 32 at predetermined intervals in such a manner as to have a predetermined inclination angle. Subsequently, as shown in FIG. 3E, after all the thermoelectric conversion material layer pieces 31 are placed in the groove 32c, a molten material composing the second thermoelectric conversion material layers 15 is poured into gaps between adjacent thermoelectric conversion material layer pieces 31 and then is cooled. After cooling, the structure retainer 32 is removed and thereby, as shown in FIG. 3F, the laminate 13 is produced. The structure retainer 32 can be separated from the laminate 13 by being rotated in the direction in which the laminate 13 is wound, and thereby can be removed. Moreover, when the structure retainer 32 is composed of a combination of a plurality of components, the structure retainer 32 can be disassembled into the respective components to be separated from the laminate 13 and thereby can be removed. Thereafter, the laminate 13 can be shaped by being subjected to a polishing treatment.

Thereafter, the first electrode 11 and the second electrode 12 are formed at both ends of the laminate 13, respectively. Thus, the thermoelectric element 10 shown in FIG. 1 is completed. In producing the first electrode 11 and the second electrode 12, various methods such as application of a conductive paste, plating, thermal spraying, solder, and bonding with a silver brazing can be used in addition to the vapor phase growth methods such as a vapor deposition method and a sputtering method.

The method of producing the thermoelectric element 10 according to the present invention is not limited particularly to the above-mentioned method as long as it is a method that provides the structure of the thermoelectric element 10. For example, by cutting and polishing not only the thermoelectric conversion material layer pieces 31 but also the material composing the second thermoelectric conversion material layers 15, the thermoelectric conversion material layer pieces having the same shape as that of the second thermoelectric conversion material layers 15 are produced and are then bonded to one another by compression bonding, and thus, the laminate 13 may be produced. Specifically, after the thermoelectric conversion material layer pieces are placed alternately in the groove 32c of the structure retainer 32 in such a manner that each of them has a predetermined inclination angle, this is subjected to roll rolling while being heated and is then cooled. Thus, the laminate 13 can be produced.

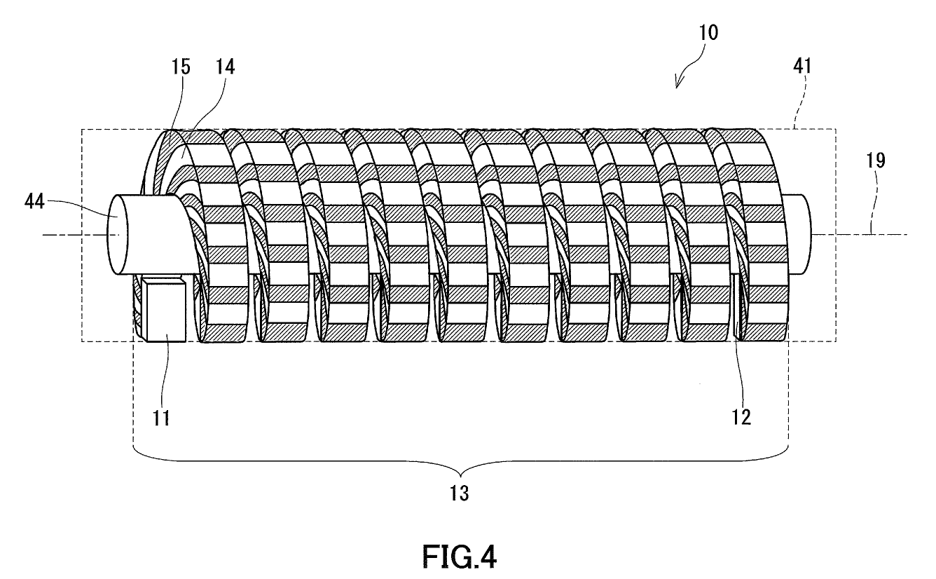

In order to operate the thermoelectric element 10, a temperature gradient is generated from the inner circumference side to the outer circumference side in the laminate 13. This generates an electromotive force in the laminate 13. The electrical power that has been generated is output through the first electrode 11 and the second electrode 12. FIG. 4 is a diagram showing an operational state of a thermoelectric element of the present invention. As shown in FIG. 4, a columnar high-temperature part 44 and a low-temperature part 41 can be placed on the inner circumference side and the outer circumference side of the thermoelectric element 10, respectively, so as to be in close contact with the thermoelectric element 10. This generates a temperature gradient from the inner circumference side to the outer circumference side of the laminate 13.

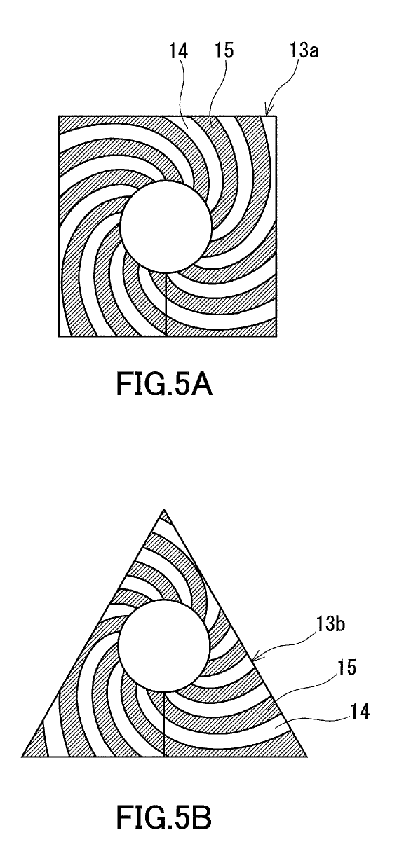

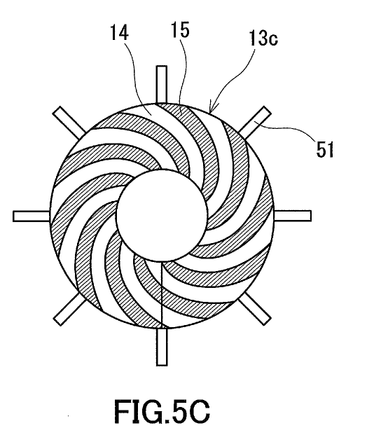

FIGS. 5A to 5C each are a diagram showing another example of the laminate of a thermoelectric element according to the present invention, which is viewed from the direction along the axis. In the laminates 13a and 13b of the thermoelectric elements shown in FIGS. 5A and 5B, the outer circumferences thereof are not of circular shape but of quadrangular shape and triangular shape. Other than this, they each have the same structure as that of the laminate 13. Even when the shape of the outer circumference is other than the circular shape as in the case of, for example, a polygonal shape, an electromotive force is generated in the laminates 13a and 13b as long as a temperature gradient is generated between the inner circumference side and the outer circumference side. Furthermore, the thermoelectric element 13c shown in FIG. 5C has fillers 51 fitted to the outer circumference. Other than this, it has the same structure as that of the laminate 13. The fillers 51 provided therefor increase the surface area of the outer circumference side of the laminate 13 and thereby increase the amount of heat radiation on the outer circumference side. This results in a high thermal conversion efficiency.

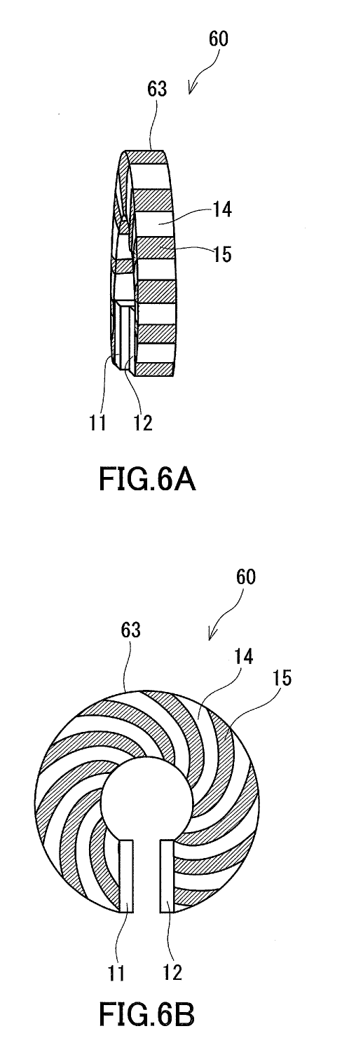

FIG. 6A is a diagram showing still another example of a thermoelectric element according to the present invention. FIG. 6B is a diagram showing the example, which is viewed from the direction along the axis. As shown in FIGS. 6A and 6B, the laminate 63 of the thermoelectric element 60 has not a spiral shape but a partially missing annular shape. Accordingly, when viewed from the direction along the axis, the inner circumference and the outer circumference of the laminate 63 each has an arc shape. Other than this, it has the same structure as that of the thermoelectric element 10. Similarly in the thermoelectric element 60, as long as a temperature gradient is generated from the inner circumference side to the outer circumference side, electrical power is output through the first electrode 11 and the second electrode 12.

The thermoelectric element 10 of the present invention can be placed while being in close contact with the outer circumference of a cylindrical or columnar heat source such as a muffler of an automobile or a pipe for discharging exhaust gas inside a factory to the outside. Thereby, since it can absorb heat efficiently from the heat source, it has a high thermoelectric conversion efficiency. Furthermore, since the laminate 13 has a shape that spirally extends around the axis 19, the portion (the inner circumference portion) that is brought into contact with the heat source can have a sufficiently wide area.

The thermoelectric element 10 of the present invention can have a high power generation performance by suitably selecting the ratio of the materials composing it, the angle θ, the inner circumferential angle, and the ratio of the inner and outer diameters. Therefore, a practical thermoelectric element 10 can be obtained. The present invention promotes application of energy conversion between heat and electricity and therefore has a high industrial value.

### Embodiment 2

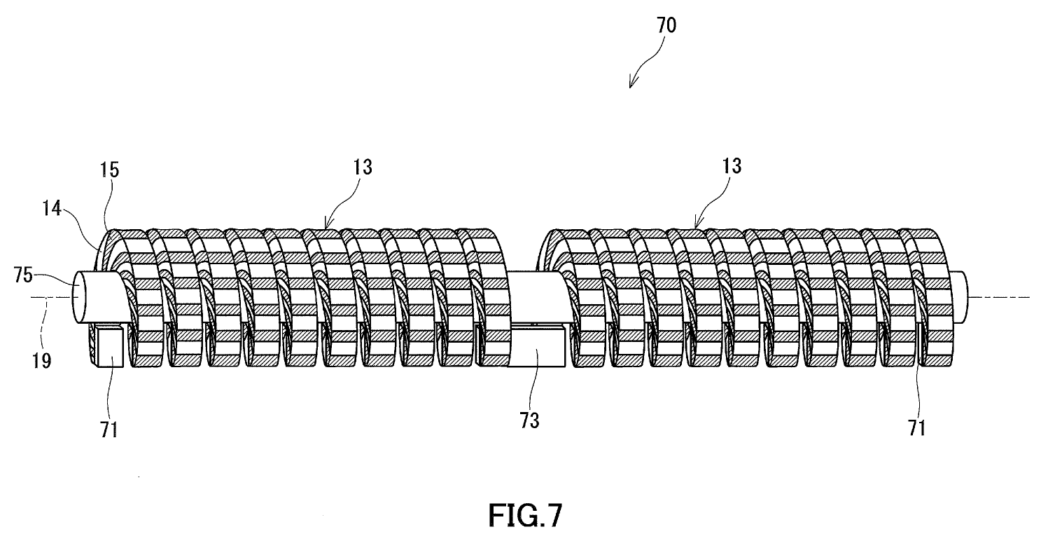

FIG. 7 is a diagram showing an example of a thermoelectric device according to the present invention. The thermoelectric device 70 has two laminates 13 that are connected electrically to each other. Since the structure of the laminate 13 was described in Embodiment 1, the description thereof is not repeated herein. One ends of the respective laminates 13 are connected electrically to each other through an interconnecting electrode 73. In each of the other ends of the respective laminates 13, an extracting electrode 71 is formed.

The materials for the extracting electrodes 71 and the interconnecting electrode 73 are not particularly limited, as long as materials with a high electrical conductivity are used. Specifically, a metal such as Cu, Ag, Mo, W, Al, Ti, Cr, Au, Pt, or In, a nitride such as TiN, or an oxide such as indium tin oxide (ITO) or SnO₂ can be used. Furthermore, a solder, a silver brazing, or a conductive paste also may be used. The interconnecting electrode 73 and the extracting electrodes 71 can be produced by using various methods such as plating and thermal spraying in addition to vapor phase growth methods such as a vapor deposition method and a sputtering method.

As shown in FIG. 7, a columnar high-temperature part 75 such as a muffler of an automobile is placed on the inner circumference side of the laminates 13 in such a manner as to be in close contact with the laminates 13. The outer circumference side of the laminates 13 is exposed to the air. Thus, a temperature gradient is generated from the inner circumference side to the outer circumference side of each laminate 13 and thereby an electromotive force is generated. The electrical power that has been generated is output through the extracting electrodes 71. The thermoelectric device 70 is configured with two laminates 13 that are connected to each other electrically in series. In the thermoelectric device 70, the portions where heat is transferred (the outer circumference surfaces and the inner circumference surfaces of the laminates 13) have larger areas as compared to the case where one laminate 13 is used. Accordingly, the thermoelectric device 70 has a higher output than that of one laminate 13. The number of the laminates 13 is not limited to two and the thermoelectric device 70 may be configured with a plurality of laminates 13 that are connected to each other electrically in series. An increase in the number of the laminates 13 increases the output voltage of the thermoelectric device 70.

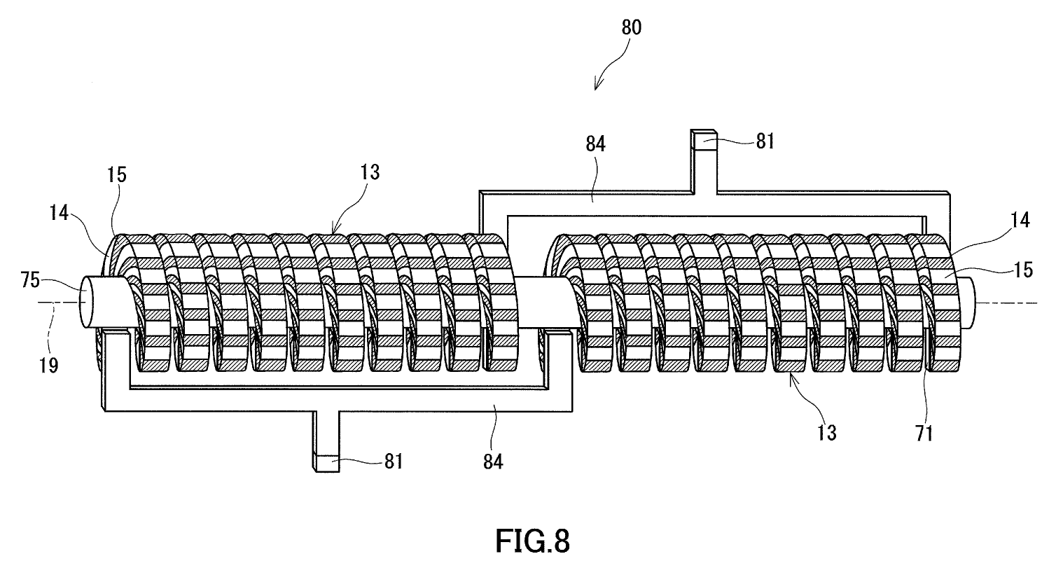

FIG. 8 is a diagram showing another example of a thermoelectric device according to the present invention. The thermoelectric device 80 has two laminates 13 that are connected electrically to each other. One ends of the respective laminates 13 are connected electrically to each other through a wiring 84. Similarly, the other ends of the respective laminates 13 are connected electrically to each other through a wiring 84. The wirings 84 are then connected to extracting electrodes 81, respectively.

The materials for the wirings 84 and the extracting electrodes 81 are not particularly limited as long as materials with a high electrical conductivity are used. Specifically, a metal such as Cu, Ag, Mo, W, Al, Ti, Cr, Au, Pt, or In, a nitride or an oxide such as TiN, indium tin oxide (ITO), or SnO₂ can be used. Furthermore, a solder, a silver brazing, or a conductive paste also may be used. The wirings 84 and the extracting electrodes 81 can be produced by using various methods such as plating and thermal spraying in addition to vapor phase growth methods such as a vapor deposition method and a sputtering method.

As shown in FIG. 8, a columnar high-temperature part 75 such as a muffler of an automobile is placed on the inner circumference side of the respective laminates 13 in such a manner as to be in close contact with the laminates 13. The outer circumference side of the laminates 13 is exposed to the air. Thus, a temperature gradient is generated from the inner circumference side to the outer circumference side of each laminate 13 and thereby an electromotive force is generated. The electrical power that has been generated is output through the extracting electrodes 81. The thermoelectric device 80 is configured with two laminates 13 that are connected to each other electrically in parallel. Therefore, in the thermoelectric device 80, the internal resistance of the whole device is low. Furthermore, even if the electrical connection of the thermoelectric device 80 is disconnected partly, the electrical connection of the whole device can be maintained. The number of the laminates 13 is not limited to two and the thermoelectric device 80 may be configured with a plurality of laminates 13 that are connected to each other electrically in parallel. Furthermore, the thermoelectric device can be configured with laminates 13 that are connected to one another in a suitable combination of series and parallel connections.

Even when the heat source has a curved surface as in the case of a columnar shape, the thermoelectric devices of the present invention each can be in close contact with the heat source and thereby heat can be transferred efficiently. Accordingly, the thermoelectric devices can generate electrical power efficiently.

### EXAMPLES

Hereinafter, further specific examples of the present invention are described.

### Example 1

A thermoelectric element 10 of Example 1 had the structure shown in FIG. 1, in which Cu was used as the material composing the first thermoelectric conversion material layers 14 and Bi was used as the material composing the second thermoelectric conversion material layers 15. The shape of the laminate 13 had an inner diameter of 100 mm, an outer diameter of 150 mm, and a width of 50 mm, and the ratio of the inner circumferential angles of Cu and Bi was 20:1. Furthermore, the angle θ was varied in the range of 0° to 240°. The width of the laminate 13 is the width in the direction along the axis 19.

The thermoelectric element 10 was produced by the production method shown in FIGS. 3D to 3F. First, a Cu plate with a size of 100 mm×100 mm and a thickness of 50 mm was subjected to cutting machining, and thereby thermoelectric conversion material layer pieces 31 with the same shape as that of the first thermoelectric conversion material layers 14 were produced (see FIGS. 3B and 3C). The inner circumferential angle of each thermoelectric conversion material layer piece 31 was set at 18°. The structure retainer 32 shown in FIG. 3A was produced by cutting a copper pipe with a diameter of 150 mm and a length of 1000 mm. Furthermore, the structure retainer 32 was produced, in which the distance of the space 21 of the laminate 13 in the direction of the axis 19 was 40 mm.

The thermoelectric conversion material layer pieces 31 were disposed in the groove 32c of the structure retainer 32 at regular intervals. After the thermoelectric conversion material layer pieces 31 were disposed, Bi heated to 650° C. was poured between them and was then air-cooled for 24 hours. After the structure retainer 32 was removed, the laminate 13 was subjected to the cutting-polishing processing.

A first electrode 11 and a second electrode 12 that were composed of Au were formed at the both ends of the laminate 13, respectively, by the sputtering method. Thus, the thermoelectric element 10 was obtained.

With respect to the thermoelectric element 10 produced by the above-mentioned method, the power generation performance thereof was evaluated. The inner circumference side of the laminate 13 was heated to 30° C. with warm water and the outer circumference side was water-cooled to 20° C. Then, the electromotive force and electrical resistance between the first electrode 11 and the second electrode 12 were measured. When the inclination angle, i.e. the angle θ, was 60°, the electromotive force was 10.5 mV and the resistance was 0.16 mΩ. From this result, the power factor was estimated to be 290 μW/cmK². In the same manner, a plurality of thermoelectric elements 10 were produced, with the angle θ being varied, and the power factors thereof were determined. Table 1 indicates the result.

TABLE 1
Layer inclination angle and power factor (μW/cmK²) of Cu/Bi layered device

| | Inclination angle (θ) | | | | | | | | | | | |
|---|---|---|---|---|---|---|---|---|---|---|---|---|
| | 0° | 15° | 30° | 45° | 60° | 75° | 90° | 105° | 120° | 180° | 210° | 240° |
| Power | 0 | 59 | 191 | 281 | 290 | 288 | 263 | 249 | 229 | 62 | 39 | 0 |
| factor | | | | | | | | | | | | |

From Table 1, it was confirmed that the thermoelectric elements 10 of Example 1 exhibited preferable power generation properties when the angle θ was in the range of 15° to 210° and exhibited further preferable power generation properties when the angle θ was particularly in the range of 30° to 120°.

### Example 2

A thermoelectric element 10 of Example 2 was produced in the same manner as in Example 1. The angle θ was fixed at 60°. A plurality of thermoelectric elements 10 were produced, with the ratio of the inner circumferential angles of Cu and Bi of the laminate 13 being varied in the range of 0.025:1 to 400:1, and the power factors thereof were determined. Table 2 indicates the result. In order to vary the ratio of the inner circumferential angles, when the thermoelectric conversion material layer pieces 31 are disposed in the groove 32c of the structure retainer 32, the intervals at which they are disposed can be varied.

TABLE 2
Ratio of Bi and power factor (μW/cmK²) of Cu/Bi layered device

| | Ratio of inner circumferential | | | | | | | | | | | |
|---|---|---|---|---|---|---|---|---|---|---|---|---|
| | angles of Cu:Bi | | | | | | | | | | | |
| | 0.025:1 | 0.05:1 | 0.2:1 | 1:1 | 5:1 | 20:1 | 40:1 | 80:1 | 100:1 | 200:1 | 250:1 | 400:1 |
| Power factor | 8 | 19 | 69 | 114 | 290 | 301 | 238 | 239 | 91 | 36 | 26 | 9 |

From Table 2, it was confirmed that the thermoelectric elements 10 of Example 2 exhibited preferable power generation properties when the ratio of the inner circumferential angles of Cu and Bi was in the range of 0.2:1 to 250:1 and exhibited further preferable power generation properties when the ratio was particularly in the range of 5:1 to 20:1.

### Example 3

A thermoelectric element 10 of Example 3 was produced in the same manner as in Example 1. The angle θ was fixed at 60°. A plurality of thermoelectric elements 10 were produced, in each of which the inner diameter of the laminate 13 was set at 100 mm, the outer diameter thereof was varied, and thereby the ratio of the inner and outer diameters was varied in the range of 1:1.05 to 1:150. The power factors thereof were then determined. Table 3 indicates the result.

TABLE 3
Ratio of inner and outer diameters and power factor (μW/cmK²)
of Cu/Bi layered device

| | Inner diameter:Outer diameter | | | | | | | | | |
|---|---|---|---|---|---|---|---|---|---|---|
| | 1:1.05 | 1:1.1 | 1:1.2 | 1:1.5 | 1:2 | 1:5 | 1:10 | 1:50 | 1:100 | 1:150 |
| Power factor | 0 | 28 | 88 | 301 | 386 | 198 | 125 | 57 | 44 | 15 |

From Table 3, it was confirmed that the thermoelectric elements 10 of Example 3 exhibited preferable power generation properties when the ratio of the inner and outer diameters was in the range of 1:1.1 to 1:100 and exhibited further preferable power generation properties when the ratio was particularly in the range of 1:1.5 to 1:2. In this case, the power factor exceeds 300 μW/cmK². This is a performance at least about six times as high as that of the π-type structure device that contains Bi used therein and that currently is being used practically.

### Example 4

A thermoelectric element was produced in the same manner as in Example 1. In the thermoelectric element, the materials composing the respective thermoelectric conversion material layers were Cu and Bi, and the respective thermoelectric conversion material layers included both layers with an angle θ of 60° and layers with an angle θ of 180°. In the laminate, the ratio of the inner circumferential angles of Cu and Bi was set at 5:1 and the ratio of the inner and outer diameters was set at 1:1.5. The conditions other than these were the same as in Example 1. In Example 4, a plurality of thermoelectric elements were produced, with the volume ratio of the layers with an angle θ of 60° and the layers with an angle θ of 180° in the laminate being varied, and were then operated under the same conditions as those employed in Example 1. Table 4 indicates the measurement result of the power factor. Table 4 indicates only the volume ratios of the layers with an angle θ of 60°. The volume ratios of the layers with an angle θ of 180° each are the remainder thereof.

TABLE 4
Volume ratio of layers with θ = 60° and power factor of Cu/Bi
layered device

| | Volume ratio of layers | | | | |
|---|---|---|---|---|---|
| | with θ = 60° (%) | | | | |
| | 100 | 75 | 50 | 25 | 0 |
| Power factor | 386 | 305 | 224 | 143 | 62 |
| (μW/cmK²) | | | | | |

### Example 5

A thermoelectric device 70 of Example 5 had the configuration shown in FIG. 7, in which two laminates 13 were connected to each other electrically in series. In the laminates 13, Cu was used as the material composing the first thermoelectric conversion material layers 14 and Bi was used as the material composing the second thermoelectric conversion material layers 15. Cu was used for the extracting electrodes 71 and the interconnecting electrode 73.

The laminates 13 were produced in the same manner as in Example 1. The angle θ was set at 60°, the inner circumferential angle of the first thermoelectric conversion material layers 14 was set at 18°, the ratio of the inner circumferential angles of Cu and Bi was set at 20:1, the inner diameter of each laminate 13 was set at 100 mm, and the ratio of the inner and outer diameters was set at 1:2. Furthermore, Cu plates with a thickness of 0.5 mm were used for the extracting electrodes 71 and the interconnecting electrode 73.

With respect to the thermoelectric device 70 of Example 5, the power generation performance thereof was evaluated. First, the resistance value between the extracting electrodes 71 was measured and was 0.34 mΩ. The inner circumference side of each laminate 13 was heated to 30° C. with warm water and the outer circumference side was maintained at 20° C. by water cooling. The open circuit electromotive force of the thermoelectric device 70 was 17.6 mV. According to this result, the power factor was estimated to be a high value, specifically, 386 μW/cmK². A maximum electrical power of 7.8 W was extracted from the thermoelectric device 70 of Example 5.

### Example 6

A thermoelectric element 10 of Example 6 had the structure shown in FIG. 1, in which Cu was used as the material composing the first thermoelectric conversion material layers 14 and Bi₂Te₃ was used as the material composing the second thermoelectric conversion material layers 15. The shape of the laminate 13 had an inner diameter of 100 mm, an outer diameter of 150 mm, and a width of 50 mm, and the ratio of the inner circumferential angles of Cu and Bi₂Te₃ was 20:1. Furthermore, the inclination angle θ was varied in the range of 0° to 240°.

First, Cu was subjected to cutting machining, and thereby thermoelectric conversion material layer pieces 31 with the same shape as that of the first thermoelectric conversion material layers 14 were produced (see FIGS. 3B and 3C). The inner circumferential angle of each thermoelectric conversion material layer piece 31 was set at 18°. Furthermore, Bi₂Te₃ was subjected to cutting machining, and thereby thermoelectric conversion material layer pieces with the same shape as that of the second thermoelectric conversion material layers 15 were produced.

The structure retainer 32 shown in FIG. 3A was produced by cutting a copper pipe with a diameter of 150 mm and a length of 1000 mm. In this case, the structure retainer 32 was produced in such a manner that the distance of the space 21 of the laminate 13 in the direction of the axis 19 was 40 mm.

The thermoelectric conversion material layer pieces 31 and the thermoelectric conversion material layer pieces composed of Bi₂Te₃ were disposed alternately in the groove 32c of the structure retainer 32. While being heated to 580° C., the laminate including those thermoelectric conversion material layer pieces that were layered together was subjected to roll press from one end to the other end at 0.01 MPa. Thereafter, it was air-cooled for 24 hours and the structure retainer 32 was then removed. After that, the laminate 13 was subjected to the cutting-polishing processing.

A first electrode 11 and a second electrode 12 that were composed of Au were formed at the both ends of the laminate 13, respectively, by the sputtering method. Thus, the thermoelectric element 10 was obtained.

With respect to the thermoelectric element 10 produced by the above-mentioned method, the power generation performance thereof was evaluated. The inner circumference side of the laminate 13 was heated to 30° C. with warm water and the outer circumference side was water-cooled to 20° C. Then, the electromotive force and electrical resistance between the first electrode 11 and the second electrode 12 were measured. When the inclination angle, i.e. the angle θ, was 60°, the electromotive force was 8.4 mV and the resistance was 3.54 mΩ. From this result, the power factor was estimated to be 257 μW/cmK². In the same manner, a plurality of thermoelectric elements 10 were produced, with the angle θ being varied, and the power factors thereof were determined. Table 5 indicates the result.

TABLE 5
Layer inclination angle and power factor (μW/cmK²) of
Cu/Bi₂Te₃ layered device

| | Inclination angle (θ) | | | | | | | | | | | |
|---|---|---|---|---|---|---|---|---|---|---|---|---|
| | 0° | 15° | 30° | 45° | 60° | 75° | 90° | 105° | 120° | 180° | 210° | 240° |
| Power | 0 | 35 | 123 | 214 | 257 | 230 | 242 | 199 | 196 | 123 | 177 | 0 |
| factor | | | | | | | | | | | | |

From Table 5, it was confirmed that the thermoelectric elements 10 of Example 6 exhibited preferable power generation properties when the angle θ was in the range of 15° to 210° and exhibited further preferable power generation properties when the angle θ was particularly in the range of 60° to 90°.

### Example 7

A thermoelectric element 10 of Example 7 was produced in the same manner as in Example 6. The angle θ was fixed at 60°. A plurality of thermoelectric elements 10 were produced, with the ratio of the inner circumferential angles of Cu and Bi₂Te₃ of the laminate 13 being varied in the range of 0.025:1 to 400:1, and the power factors thereof were determined. Table 6 indicates the result.

TABLE 6
Ratio of Bi₂Te₃ and power factor (μW/cmK²) of
Cu/Bi₂Te₃ layered device

| | Ratio of inner circumferential | | | | | | | | | | | |
|---|---|---|---|---|---|---|---|---|---|---|---|---|
| | angles of Cu:Bi₂Te₃ | | | | | | | | | | | |
| | 0.025:1 | 0.05:1 | 0.2:1 | 1:1 | 5:1 | 20:1 | 40:1 | 80:1 | 100:1 | 200:1 | 250:1 | 400:1 |
| Power factor | 27 | 34 | 50 | 135 | 257 | 315 | 248 | 148 | 119 | 41 | 36 | 9 |

From Table 6, it was confirmed that the thermoelectric elements 10 of Example 7 exhibited preferable power generation properties when the ratio of the inner circumferential angles of Cu and Bi₂Te₃ was in the range of 0.05:1 to 250:1 and exhibited further preferable power generation properties when the ratio was particularly in the range of 5:1 to 40:1.

### Example 8

A thermoelectric element 10 of Example 8 was produced in the same manner as in Example 6. The angle θ was fixed at 60°. A plurality of thermoelectric elements 10 were produced, in each of which the inner diameter of the laminate 13 was set at 100 mm, the outer diameter thereof was varied, and thereby the ratio of the inner and outer diameters was varied in the range of 1:1.05 to 1:150. The power factors thereof were then determined. Table 7 indicates the result.

TABLE 7
Ratio of inner and outer diameters and power factor (μW/cmK²)
of Cu/Bi₂Te₃ layered device

| | Inner diameter:Outer | | | | | | | | | |
|---|---|---|---|---|---|---|---|---|---|---|
| | diameter | | | | | | | | | |
| | 1:1.05 | 1:1.1 | 1:1.2 | 1:1.5 | 1:2 | 1:5 | 1:10 | 1:50 | 1:100 | 1:150 |
| Power factor | 0 | 94 | 221 | 315 | 280 | 101 | 58 | 22 | 16 | 15 |

From Table 7, it was confirmed that the thermoelectric elements 10 of Example 8 exhibited preferable power generation properties when the ratio of the inner and outer diameters was in the range of 1:1.1 to 1:10 and exhibited further preferable power generation properties when the ratio was particularly 1:1.5. In this case, the power factor exceeds 300 μW/cmK². This is a performance at least about six times as high as that of the π-type structure device that contains Bi used therein and that currently is being used practically.

### Example 9

A thermoelectric element was produced in the same manner as in Example 6. In the thermoelectric element, the materials composing the respective thermoelectric conversion material layers were Cu and Bi₂Te₃, and the respective thermoelectric conversion material layers included both layers with an angle θ of 60° and layers with an angle θ of 180°. In the laminate, the ratio of the inner circumferential angles of Cu and Bi₂Te₃ was set at 5:1 and the ratio of the inner and outer diameters was set at 1:1.5. The conditions other than these were the same as in Example 6. In Example 9, a plurality of thermoelectric elements were produced, with the volume ratio of the layers with an angle θ of 60° and the layers with an angle θ of 180° in the laminate being varied, and were then operated under the same conditions as those employed in Example 1. Table 8 indicates the measurement result of the power factor. Table 8 indicates only the volume ratios of the layers with an angle θ of 60°. The volume ratios of the layers with an angle θ of 180° each are the remainder thereof.

TABLE 8
Volume ratio of layers with θ = 60° and power factor of
Cu/Bi₂Te₃ layered device

| | Volume ratio of layers | | | | |
|---|---|---|---|---|---|
| | with θ = 60° (%) | | | | |
| | 100 | 75 | 50 | 25 | 0 |
| Power factor | 257 | 224 | 190 | 157 | 123 |
| (μW/cmK²) | | | | | |

### Example 10

A thermoelectric device 70 of Example 10 had the configuration shown in FIG. 7, in which two laminates 13 were connected to each other electrically in series. In the laminates 13, Cu was used as the material composing the first thermoelectric conversion material layers 14 and Bi₂Te₃ was used as the material composing the second thermoelectric conversion material layers 15. Cu was used for the extracting electrodes 71 and the interconnecting electrode 73.

The laminates 13 were produced in the same manner as in Example 6. The angle θ was set at 60°, the inner circumferential angle of the first thermoelectric conversion material layers 14 was set at 18°, the ratio of the inner circumferential angles of Cu and Bi₂Te₃ was set at 20:1, the inner diameter of each laminate 13 was set at 100 mm, and the ratio of the inner and outer diameters was set at 1:1.5. Furthermore, Cu plates with a thickness of 0.5 mm were used for the extracting electrodes 71 and the interconnecting electrode 73.

With respect to the thermoelectric device 70 of Example 10, the power generation performance thereof was evaluated. First, the resistance value between the extracting electrodes 71 was measured and was 0.32 mΩ. The inner circumference side of each laminate 13 was heated to 30° C. with warm water and the outer circumference side was maintained at 20° C. by water cooling. The open circuit electromotive force of the thermoelectric device 70 was 41.4 mV. According to this result, the power factor was estimated to be a high value, specifically, 315 μW/cmK². A maximum electrical power of 6.4 W was extracted from the thermoelectric device 70 of Example 10.

### Example 11

A thermoelectric element 10 of Example 11 had the structure shown in FIG. 1, in which Cu was used as the material composing the first thermoelectric conversion material layers 14 and PbTe was used as the material composing the second thermoelectric conversion material layers 15. The shape of the laminate 13 had an inner diameter of 100 mm, an outer diameter of 150 mm, and a width of 50 mm, and the ratio of the inner circumferential angles of Cu and PbTe was 20:1. Furthermore, the angle θ was varied in the range of 0° to 240°.

First, Cu was subjected to cutting machining, and thereby thermoelectric conversion material layer pieces 31 with the same shape as that of the first thermoelectric conversion material layers 14 were produced (see FIGS. 3B and 3C). The inner circumferential angle of each thermoelectric conversion material layer piece 31 was set at 18°. Furthermore, PbTe was subjected to cutting machining, and thereby thermoelectric conversion material layer pieces with the same shape as that of the second thermoelectric conversion material layers 15 were produced.

The structure retainer 32 shown in FIG. 3A was produced by cutting a copper pipe with a diameter of 150 mm and a length of 1000 mm. In this case, the structure retainer 32 was produced in such a manner that the distance of the space 21 of the laminate 13 in the direction of the axis 19 was 40 mm.

The thermoelectric conversion material layer pieces 31 and the thermoelectric conversion material layer pieces composed of PbTe were disposed alternately in the groove 32c of the structure retainer 32. While being heated to 800° C., the laminate including those thermoelectric conversion material layer pieces that were layered together was subjected to roll press from one end to the other end at 0.01 MPa. Thereafter, it was air-cooled for 24 hours and the structure retainer 32 was then removed. After that, the laminate 13 was subjected to the cutting-polishing processing.

A first electrode 11 and a second electrode 12 that were composed of Au were formed at the both ends of the laminate 13, respectively, by the sputtering method. Thus, the thermoelectric element 10 was obtained.

With respect to the thermoelectric element 10 produced by the above-mentioned method, the power generation performance thereof was evaluated. The inner circumference side of the laminate 13 was heated to 30° C. with warm water and the outer circumference side was water-cooled to 20° C. Then, the electromotive force and electrical resistance between the first electrode 11 and the second electrode 12 were measured. When the inclination angle, i.e. the angle θ, was 60°, the electromotive force was 6.8 mV and the resistance was 3.8 mΩ. From this result, the power factor was estimated to be 136 μW/cmK². In the same manner, a plurality of thermoelectric elements 10 were produced, with the angle θ being varied, and the power factors thereof were determined. Table 9 indicates the result.

TABLE 9
Layer inclination angle and power factor (μW/cmK²) of Cu/PbTe layered device

| | Inclination angle (θ) | | | | | | | | | | | |
|---|---|---|---|---|---|---|---|---|---|---|---|---|
| | 0° | 15° | 30° | 45° | 60° | 75° | 90° | 105° | 120° | 180° | 210° | 240° |
| Power | 0 | 18 | 63 | 111 | 136 | 125 | 135 | 115 | 117 | 106 | 132 | 0 |
| factor | | | | | | | | | | | | |

From Table 9, it was confirmed that the thermoelectric elements 10 of Example 11 exhibited preferable power generation properties when the angle θ was in the range of 15° to 210° and exhibited further preferable power generation properties when the angle θ was particularly in the range of 60° to 90°.

### Example 12

A thermoelectric element 10 of Example 12 was produced in the same manner as in Example 11. The angle θ was fixed at 60°. A plurality of thermoelectric elements 10 were produced, with the ratio of the inner circumferential angles of Cu and PbTe of the laminate 13 being varied in the range of 0.025:1 to 400:1, and the power factors thereof were determined. Table 10 indicates the result.

TABLE 10
Ratio of PbTe and power factor (μW/cmK²) of Cu/PbTe layered device

| | Ratio of inner circumferential | | | | | | | | | | | |
|---|---|---|---|---|---|---|---|---|---|---|---|---|
| | angles of Cu:PbTe | | | | | | | | | | | |
| | 0.025:1 | 0.05:1 | 0.2:1 | 1:1 | 5:1 | 20:1 | 40:1 | 80:1 | 100:1 | 200:1 | 250:1 | 400:1 |
| Power factor | 20 | 23 | 30 | 77 | 136 | 157 | 122 | 76 | 64 | 26 | 24 | 6 |

From Table 10, it was confirmed that the thermoelectric elements 10 of Example 12 exhibited preferable power generation properties when the ratio of the inner circumferential angles of Cu and PbTe was in the range of 0.2:1 to 100:1 and exhibited further preferable power generation properties when the ratio was particularly in the range of 5:1 to 40:1.

### Example 13

A thermoelectric element 10 of Example 13 was produced in the same manner as in Example 11. The angle θ was fixed at 60°. A plurality of thermoelectric elements 10 were produced, in each of which the inner diameter of the laminate 13 was set at 100 mm, the outer diameter thereof was varied, and thereby the ratio of the inner and outer diameters was varied in the range of 1:1.01 to 1:50. The power factors thereof were then determined. Table 11 indicates the result.

TABLE 11
Ratio of inner and outer diameters and power factor (μW/cmK²)
of Cu/PbTe layered device

| | Inner diameter:Outer | | | | | | | | |
|---|---|---|---|---|---|---|---|---|---|
| | diameter | | | | | | | | |
| | 1:1.01 | 1:1.05 | 1:1.1 | 1:1.2 | 1:1.5 | 1:2 | 1:5 | 1:10 | 1:50 |
| Power factor | 8 | 28 | 89 | 153 | 156 | 125 | 42 | 23 | 8 |

From Table 11, it was confirmed that the thermoelectric elements 10 of Example 13 exhibited preferable power generation properties when the ratio of the inner and outer diameters was in the range of 1:1.05 to 1:10 and exhibited further preferable power generation properties when the ratio was particularly in the range of 1:1.2 to 1:1.5. In this case, the power factor exceeds 150 μW/cmK². This is a high performance at least about three times as high as that of the π-type structure device that contains Bi used therein and that currently is being used practically.

### Example 14

A thermoelectric element was produced in the same manner as in Example 11. In the thermoelectric element, the materials composing the respective thermoelectric conversion material layers were Cu and PbTe, and the respective thermoelectric conversion material layers included both layers with an angle θ of 60° and layers with an angle θ of 180°. In the laminate, the ratio of the inner circumferential angles of Cu and PbTe was set at 5:1 and the ratio of the inner and outer diameters was set at 1:1.5. The conditions other than these were the same as in Example 11. In Example 14, a plurality of thermoelectric elements were produced, with the volume ratio of the layers with an angle θ of 60° and the layers with an angle θ of 180° in the laminate being varied, and were then operated under the same conditions as those employed in Example 11. Table 12 indicates the measurement result of the power factor. Table 12 indicates only the volume ratios of the layers with an angle θ of 60°. The volume ratios of the layers with an angle θ of 180° each are the remainder thereof.

TABLE 12
Volume ratio of layers with θ = 60° and power factor of
Cu/PbTe layered device

| | Volume ratio of layers | | | | |
|---|---|---|---|---|---|
| | with θ = 60° (%) | | | | |
| | 100 | 75 | 50 | 25 | 0 |
| Power factor | 136 | 129 | 121 | 114 | 106 |
| (μW/cmK²) | | | | | |

### Example 15

A thermoelectric device 70 of Example 15 had the electrical configuration shown in FIG. 7, in which two laminates 13 were connected to each other electrically in series. In the laminates 13, Cu was used as the material composing the first thermoelectric conversion material layers 14 and PbTe was used as the material composing the second thermoelectric conversion material layers 15. Cu was used for the extracting electrodes 71 and the interconnecting electrode 73.

The laminates 13 were produced in the same manner as in Example 11. The angle θ was set at 60°, the inner circumferential angle of the first thermoelectric conversion material layers 14 was set at 18°, the ratio of the inner circumferential angles of Cu and PbTe was set at 20:1, the inner diameter of each laminate 13 was set at 100 mm, and the ratio of the inner and outer diameters was set at 1:1.5. Furthermore, Cu plates with a thickness of 0.5 mm were used for the extracting electrodes 71 and the interconnecting electrode 73.

With respect to the thermoelectric device 70 of Example 15, the power generation performance thereof was evaluated. First, the resistance value between the extracting electrodes 71 was measured and was 0.32 mΩ. The inner circumference side of each laminate 13 was heated to 30° C. with warm water and the outer circumference side was maintained at 20° C. by water cooling. The open circuit electromotive force of the thermoelectric device 70 was 61.5 mV. According to this result, the power factor was estimated to be a high value, specifically, 156 μW/cmK². A maximum electrical power of 3.2 W was extracted from the thermoelectric device 70 of Example 15.

### INDUSTRIAL APPLICABILITY

The thermoelectric elements and thermoelectric devices according to the present invention have excellent power generation properties and can be used for, for example, electric generators that utilize heat of, for example, an exhaust gas discharged from a factory or an automobile. Furthermore, they also can be used for, for example, small mobile electric generators.

1. A thermoelectric element, comprising:
a laminate with two different types of thermoelectric conversion materials that are layered alternately from one end to the other end, and
a first electrode and a second electrode that are disposed at both ends of the laminate, respectively,
wherein the laminate has a shape surrounding a straight line axis from the one end to the other end, and
when viewed from the direction along the axis, the laminate has an inner circumference with a circular or arc shape and each boundary between respective layers formed of the two different types of thermoelectric conversion materials is disposed in such a manner as to separate from a straight line as the boundary approaches an outer circumference from the inner circumference of the laminate, where the straight line passes an inner circumference-side edge point of the boundary, with the axis being a starting point thereof.

2. The thermoelectric element according to claim 1, wherein the laminate has a shape that is a spiral shape and that surrounds the axis from the one end to the other end.

3. The thermoelectric element according to claim 1, wherein when the laminate is viewed from the direction along the axis,
the respective layers formed of the two different types of thermoelectric conversion materials are curved.

4. The thermoelectric element according to claim 1, wherein when the laminate is viewed from the direction along the axis,
a line segment extending between the inner circumference-side edge point and an outer circumference-side edge point of each boundary between the respective layers formed of the two different types of thermoelectric conversion materials, and
a straight line passing the inner circumference-side edge point, with the axis being the starting point, form an angle θ of 15° to 210°.

5. The thermoelectric element according to claim 1, wherein at least one of the thermoelectric conversion materials contains Bi.

6. The thermoelectric element according to claim 5, wherein the laminate is composed of first thermoelectric conversion material layers and second thermoelectric conversion material layers that are layered alternately,
the second thermoelectric conversion material layers each are formed of the thermoelectric conversion material containing Bi, and
the ratio of inner circumferential angles is in a range of 0.2:1 to 250:1, where the inner circumferential angles are values that indicate the thicknesses of the first thermoelectric conversion material layers and the second thermoelectric conversion material layers in a circumferential direction in the inner circumference of the laminate when the laminate is viewed from the direction along the axis, in terms of angles formed with the axis being a vertex.

7. The thermoelectric element according to claim 5, wherein when the laminate is viewed from the direction along the axis, the outer circumference of the laminate has a circular or arc shape, and
the ratio of inner and outer diameters of the laminate is in a range of 1:1.1 to 1:100.

8. The thermoelectric element according to claim 1, wherein at least one of the thermoelectric conversion materials contains Bi and Te.

9. The thermoelectric element according to claim 8, wherein the laminate is composed of first thermoelectric conversion material layers and second thermoelectric conversion material layers that are layered alternately,
the second thermoelectric conversion material layers each are formed of the thermoelectric conversion material containing Bi and Te, and
the ratio of inner circumferential angles is in a range of 0.05:1 to 250:1, where the inner circumferential angles are values that indicate the thicknesses of the first thermoelectric conversion material layers and the second thermoelectric conversion material layers in a circumferential direction in the inner circumference of the laminate when the laminate is viewed from the direction along the axis, in terms of angles formed with the axis being a vertex.

10. The thermoelectric element according to claim 8, wherein when the laminate is viewed from the direction along the axis, the outer circumference of the laminate has a circular or arc shape, and
the ratio of inner and outer diameters of the laminate is in a range of 1:1.1 to 1:10.

11. The thermoelectric element according to claim 1, wherein at least one of the thermoelectric conversion materials contains Pb and Te.

12. The thermoelectric element according to claim 11, wherein the laminate is composed of first thermoelectric conversion material layers and second thermoelectric conversion material layers that are layered alternately,
the second thermoelectric conversion material layers each are formed of the thermoelectric conversion material containing Pb and Te, and
the ratio of inner circumferential angles is in a range of 0.2:1 to 100:1, where the inner circumferential angles are values that indicate the thicknesses of the first thermoelectric conversion material layers and the second thermoelectric conversion material layers in a circumferential direction in the inner circumference of the laminate when the laminate is viewed from the direction along the axis, in terms of angles formed with the axis being a vertex.

13. The thermoelectric element according to claim 11, wherein when the laminate is viewed from the direction along the axis, the outer circumference of the laminate has a circular or arc shape, and
the ratio of inner and outer diameters of the laminate is in a range of 1:1.05 to 1:10.

14. A thermoelectric device comprising a plurality of thermoelectric elements,
wherein the plurality of thermoelectric elements each comprise a laminate with two different types of thermoelectric conversion materials that are layered alternately from one end to the other end, the laminate has a shape surrounding a straight line axis from the one end to the other end, when viewed from the direction along the axis, the laminate has an inner circumference with a circular or arc shape and each boundary between respective layers formed of the two different types of thermoelectric conversion materials is disposed in such a manner as to separate from a straight line as the boundary approaches an outer circumference from the inner circumference of the laminate, where the straight line passes an inner circumference-side edge point of the boundary, with the axis being a starting point thereof, and
the plurality of thermoelectric elements are connected to each other electrically in series.

15. A thermoelectric device comprising a plurality of thermoelectric elements,
wherein the plurality of thermoelectric elements each comprise a laminate with two different types of thermoelectric conversion materials that are layered alternately from one end to the other end, the laminate has a shape surrounding a straight line axis from the one end to the other end, when viewed from the direction along the axis, the laminate has an inner circumference with a circular or arc shape and each boundary between respective layers formed of the two different types of thermoelectric conversion materials is disposed in such a manner as to separate from a straight line as the boundary approaches an outer circumference from the inner circumference of the laminate, where the straight line passes an inner circumference-side edge point of the boundary, with the axis being a starting point thereof, and
the plurality of thermoelectric elements are connected to each other electrically in parallel.

16. A thermoelectric element, comprising:
a laminate formed of a material that comprises two different types of thermoelectric conversion materials layered alternately from one end to the other end and that is disposed so as to incline towards an outer circumference from an inner circumference of the material with respect to a straight line extending between a center point surrounded by the material and a point on a boundary between the two different types of thermoelectric conversion materials on the inner circumference of the material,
a first electrode disposed at the one end, and
a second electrode disposed at the other end.
